(19) United States
(12) Patent Application Publication
(10) Pub. No.: US 2016/0197575 A1
(43) Pub. Date: Jul. 7, 2016

(54) PHOTOVOLTAIC-BASED FULLY INTEGRATED PORTABLE POWER SYSTEMS

(71) Applicant: Ascent Solar Technologies, Inc., Thornton, CO (US)

(72) Inventors: Joseph H. Armstrong, Littleton, CO (US); Stephanie Persha Retureta, Highlands Ranch, CO (US); Inbo Lee, Broomfield, CO (US); Rafael Eduardo Gutierrez, Lafayette, CO (US)

(21) Appl. No.: 14/987,214

(22) Filed: Jan. 4, 2016

Related U.S. Application Data
(60) Provisional application No. 62/099,530, filed on Jan. 4, 2015.

(51) Int. Cl. H02S 10/40; H01L 31/0392; H02J 7/35; H02J 7/00; H02S 30/20; H02B 1/28

(52) U.S. Cl. CPC H02S 10/40; H02S 30/20; H02B 1/28; H02J 7/355; H02J 7/0029; H01L 31/03928; H01L 31/03926; H01L 31/03921; H02J 2007/0039

(57) ABSTRACT

A photovoltaic-based fully integrated portable power system includes (1) an integrated power management, storage, and distribution (MSD) subsystem including a case having an opening, (2) a flexible photovoltaic module capable of being disposed in at least a folded position and an unfolded position, where a portion of the flexible photovoltaic module is disposed over the opening of the case, and (3) a mounting plate disposed on the flexible photovoltaic module and over the opening of the case, such that the portion of the flexible photovoltaic module is sandwiched between the MSD subsystem and the mounting plate.

### RELATED APPLICATIONS

This application claims benefit of priority to U.S. Provisional Patent Application Ser. No. 62/099,530, filed Jan. 4, 2015, which is incorporated herein by reference.

### BACKGROUND

Photovoltaic (PV) power systems have been widely used for generating electrical power from sunlight. Most often, these systems have consisted of heavy, rigid glass PV panels that generate direct current (DC), and a balance of systems (BOS) that may consist of a combination of power management circuitry, battery storage with charge control circuitry, and possibly an inverter that converts the DC power to alternating current (AC) to operate household components.

One advantage of such systems is that they do not necessarily require connection to an existing power grid, and as such, can provide power in remote locations. While portable versions of these systems exist, the rigid nature of the PV panels, as well as the significant weight of sealed lead acid (SLA) batteries commonly used therein, prohibit their wide spread use.

Lightweight and flexible PV modules, frequently referred to as PV blankets, have been developed as an alternative to rigid glass PV panels. PV blankets are commercially available and are sufficiently light to allow for portable power generation. Conventional portable power systems including PV blankets suffer from a number of significant disadvantages, however. For example, it can be difficult to find a PV blanket that is compatible with a given BOS, or vice versa, because PV blankets and BOS are often manufactured by different vendors and designed according to different specifications.

Additionally, conventional portable PV power systems require a plurality of discrete components, i.e., components separate from the PV blanket, which are electrically coupled to the PV blanket and/or each other via cables. This collection of discrete components and interconnecting cables may undesirably clutter an area where the portable PV power system is deployed. The requirement that the discrete components be interconnected via cables may also make system assembly difficult, particularly for an untrained user. Furthermore, the discrete components and/or interconnecting cables may be misplaced, and in some cases, the discrete components are fragile and therefore prone to physical damage. The interconnecting cables may also present a tripping hazard.

Moreover, conventional portable PV power systems will typically not operate at their maximum power point, especially when operated by a person who is not an expert in PV systems. To help appreciate this point, consider the electrical characteristics of PV devices.

Power output of a photovoltaic device, such as a single PV cell or a PV module including a plurality of PV cells, is described as DC, but the values are dynamic, and voltage and current depend heavily on the electrical load imparted upon the photovoltaic device. At zero load, or open circuit, the PV device generates no current and presents its highest voltage, commonly referred to as open-circuit voltage (V_{OC}). As the electrical load attached to the PV device increases, its voltage will remain relatively stable until reaching a point where the voltage will continue to decrease with increasing load (i.e., increasing electrical current). When the photovoltaic device is electrically shorted, the voltage across the device is zero, and the current is referred to as the short-circuit current (or I_{sc}).

Electrical power (P) is calculated by the product of the voltage and current. Where the voltage is relatively stable as current (load) increases, the amount of electrical power generated also increases. As the voltage begins to drop with increasing current (load), the power generated decreases. At the point where peak power output is achieved, commonly referred to as the maximum power point, the voltage and current is commonly referred to as Vₘₐₓ and Iₘₐₓ, respectively.

For example, FIG. 1 illustrates a dynamic response 100 of an exemplary PV device, such as a PV cell or a module of a plurality of PV cells, at 100% light intensity and at 70% light intensity. As illustrated, the PV device will generate a V_{oc} 102 at no load and 100% light intensity. If the PV device is electrically shorted (e.g. both leads are connected together), there is no voltage across the device, and I_{sc} 104 flows through the photovoltaic device at 100% light intensity. The PV device has a maximum power point 106 at 100% light intensity.

However, performance of the PV device is significantly different if less light impinges upon the front surface. For example, both V_{OC} and I_{sc} shift noticeably lower to V_{oc} 108 and I_{sc} 110, respectively, at 70% light intensity. Consequentially, the maximum power point 112 at 70% light intensity is lower and occurs at a lower output voltage than maximum power point 106 at 100% light intensity. Thus, if electronics attached to the PV device are designed to run at a fixed voltage corresponding to maximum power point 106, the PV device will not operate at its maximum power point at 70% light intensity, because the operating voltage will not correspond to the maximum power point at 70% light intensity.

Additionally, environmental conditions affect the maximum power available, as well as the voltage and current at these peak conditions. These environmental conditions include the angle of sunlight impinging the PV device, the ambient temperature at the device's location, the increasing temperature of the PV device as the sunlight impinges upon it, the interference of sunlight reaching the PV device due to smoke, fog, dust and dirt, precipitation, leaves, grass, and other naturally occurring phenomenon. Given that the very nature of portable power systems dictates that they may not be ideally inclined towards the sun, operating under ideal temperature conditions, or be free of environmental contaminants blocking sunlight, the PV devices likely will not operate at their maximum performance levels as measured under standard test conditions.

Any circuitry that is intended to connect to a PV device will ideally cause the PV device to operate at a voltage and current corresponding to the PV device's maximum power point. However, as stated above, the maximum power point can change for a variety of reasons, and as such, a means for adjusting the load that the photovoltaic device experiences must be constantly adjusted to maximize its performance. Furthermore, there is no guarantee that this voltage/current corresponding to maximum power point has any relation to what the attached load may require.

Accordingly, conventional portable power systems will typically not operate at their maximum possible level for a number of reasons. Additionally, as the voltage and current at maximum power point may vary under various conditions, PV blankets must be installed and operated by someone who understands how they operate, otherwise they will likely not obtain high performance. For someone who wants to operate a portable PV system, but is not an expert in portable PV systems, clearly this is a disadvantage.

Also, as photovoltaics only produce power when exposed to a sufficient amount of sunlight, temporary shading or prolonged absence of light, such as at night, render a portable photovoltaic power system inoperable. In some instances, the shading may be only momentary, yet it will be sufficient to disable the charging protocol of today's intelligent consumer electronics (CE), and when sunlight conditions re-enable the operation of the portable photovoltaic power system, the intelligent consumer electronics may not recognize that the photovoltaic power system is again able to provide a charge for the device, thus making unattended operation result in insufficient charging.

### SUMMARY

Applicant has developed photovoltaic-based fully integrated portable power systems that may at least partially overcome one or more of the problems discussed above. These fully integrated portable power systems advantageously include both BOS and photovoltaic devices co-packaged in a single assembly, thereby potentially eliminating the need for multiple discrete components and associated interconnecting cables. Additionally, in certain embodiments, the BOS include maximum power point tracking (MPPT) circuitry, which as discussed below, is capable of causing the photovoltaic devices to operate substantially at their maximum point without user intervention, thereby potentially allowing the portable power systems to achieve high performance, even when used by a person who is not an expert in portable PV systems. The MPPT circuitry can be either passive or dynamic in nature. A passive system clamps the voltage of the PV circuit to Vₘₐₓ, whereas a dynamic system will adjust the PV performance constantly. A dynamic system adds to the complexity of the system but can account for regaining 10-30% of the available power under extreme conditions.

Furthermore, certain embodiments of the systems are sized to adequately charge CE devices while maintaining a sufficiently small form factor to enable easy storage in clothing, backpacks, suitcases, and other small repositories. Moreover, in some embodiments, an external charging solution from a household outlet optionally provides backup to the system in the event that sunlight is not available to charge the integrated portable power system.

The BOS optionally additionally include an energy storage subsystem, such as a battery subsystem and associated charge controlling circuitry, to provide stable power, even during temporary shading. In certain embodiments, the battery subsystem includes lithium-ion (Li-Ion) and/or lithium-polymer (LiPo) batteries to promote lightweight, robust, powerful, and stable energy storage, which is particularly well-suited for outdoor portable power applications. Furthermore, in some embodiments, MPPT circuitry also provides both battery charge management and load protection, such as overcurrent protection.

In particular embodiments, the BOS further include power conversion circuitry for providing one or more regulated power outputs. Some embodiments include a 5 VDC regulated output voltage rail for universal serial bus (USB) charging, and/or a higher power regulated output voltage rail at voltages ranging from 6 VDC up to 48 VDC. Certain embodiments also include an inverter to convert DC from an internal bus voltage rail to AC, such as to operate household equipment. Some embodiments include a proprietary sealed physical electrical contact that is maintained by magnetic or a physical means. Certain embodiments have wireless charging capability to eliminate the need for cabling between the portable power system and the device to be charged.

Some embodiments are also suitable for extended outdoor use. In these embodiments, the photovoltaic module is designed to prevent water and water vapor ingress to promote long-term operation of the photovoltaic module. Such embodiments can be realized by waterproof connectors, or by waterproof covers that provide protection to the electronics when installed properly over the connector. Additionally, in these embodiments, a case is provided for the electronics and battery system that prevents water ingress, and all connectors, fuses, and switchgear are designed to prevent water ingress as well. Electronics are optionally potted after assembly to further protect them from moisture ingress.

In one embodiment, a photovoltaic-based fully integrated portable power system includes (1) an integrated power management, storage, and distribution (MSD) subsystem including a case having an opening, (2) a flexible photovoltaic module capable of being disposed in at least a folded position and an unfolded position, where a portion of the flexible photovoltaic module is disposed over the opening of the case, and (3) a mounting plate disposed on the flexible photovoltaic module and over the opening of the case, such that the portion of the flexible photovoltaic module is sandwiched between the MSD subsystem and the mounting plate.

### BRIEF DESCRIPTION OF THE DRAWINGS

FIG. 1 illustrates the relationship between voltage and current of an exemplary photovoltaic device, along with the corresponding power output as a function of electrical load (current).

FIG. 2 is a block diagram of a photovoltaic-based fully integrated portable power system, according to an embodiment.

FIG. 3 is a top plan view of an integrated power management, storage, and distribution subsystem, according to an embodiment.

FIGS. 4-7 are each different perspective views of a photovoltaic-based fully integrated portable power system, according to an embodiment.

FIG. 8 illustrates one embodiment of the photovoltaic-based fully integrated portable power system of FIGS. 4-7, with a flexible photovoltaic module in its unfolded (deployed) position.

FIG. 9 illustrates the photovoltaic-based fully integrated portable power system of FIGS. 4-7 with its flexible photovoltaic module in its folded (stowed) position.

FIG. 10 is an exploded perspective view of the FIG. 3 integrated power management, storage, and distribution subsystem.

FIG. 11 is a block diagram of a pocket-sized photovoltaic-based fully integrated portable power system, according to an embodiment.

FIG. 12 is a top plan view of another integrated power management, storage, and distribution subsystem according to an embodiment.

FIG. 13 is a perspective view of a pocket-sized photovoltaic-based fully integrated portable power system, according to an embodiment.

FIGS. 14, 15 and 16 are a top, side, and end view of the pocket-sized photovoltaic-based fully integrated portable power system of FIG. 13, respectively.

FIG. 17 is a series of photographs of one embodiment of the pocket-sized portable power system of FIGS. 13-16, with a flexible photovoltaic module in sequence of deployment.

FIG. 18 is a series of photographs of four views of one embodiment of the pocket-sized photovoltaic-based fully integrated portable power system of FIGS. 13-17 in folded (stowed) positions.

FIG. 19 is two photographs of the strap and latch view of one embodiment of the pocket-sized photovoltaic-based fully integrated portable power system of FIGS. 13-17.

### DETAILED DESCRIPTION OF THE EMBODIMENTS

It is noted that, for purposes of illustrative clarity, certain elements in the drawings may not be drawn to scale. Specific instances of an item may be referred to by use of a numeral in parentheses (e.g., USB connector 316(1)) while numerals without parentheses refer to any such item (e.g., USB connectors 316). In the present disclosure, “cm” refers to centimeters, “m” refers to meters, “A” refers to amperes, “mA” refers to milliamperes, and “V” refers to volts.

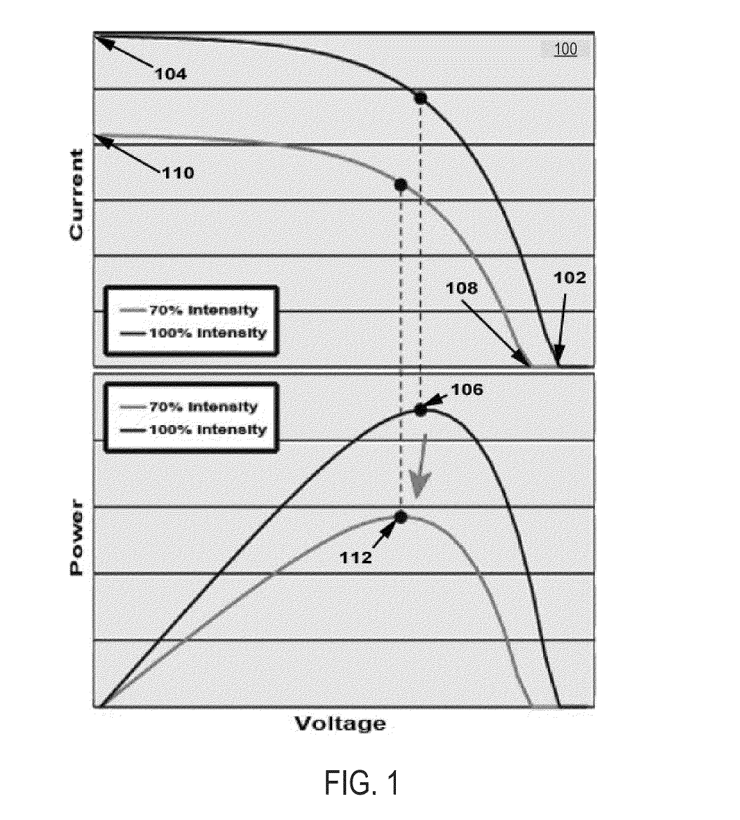

As discussed above, certain embodiments of the PV-based fully integrated portable power systems developed by Applicant include MPPT circuitry. In some embodiments, the MPPT circuitry is active and designed to adjust the voltage/current position along the power curve to determine the position of the maximum power point. This can be achieved by scanning the load that the PV device ‘sees’, and as the scan proceeds, the MPPT circuitry identifies the position of the maximum power point and maintains PV device operation at this voltage point and current point. Thus, the MPPT circuitry does not need to know the conditions that the PV device is actually experiencing; rather, the MPPT circuitry will adjust its input impedance, thereby adjusting the load condition that the PV device is ‘seeing’, to identify and lock into the maximum power point. For example, if a PV device has characteristics like that illustrated in FIG. 1, the MPPT circuitry will adjust its input impedance such that the PV device operates at maximum power point 106 or 112 at 100% and 70% light intensity, respectively. By effectively decoupling the actual load that the PV device ‘sees’ from the PV device operation, the MPPT can continuously adjust the effective PV load to ensure the PV device can operate at maximum efficiency.

In some other embodiments, the MPPT circuitry is passive. In these embodiments, the MPPT circuitry sets the voltage/current at its maximum power points based on standard test conditions.

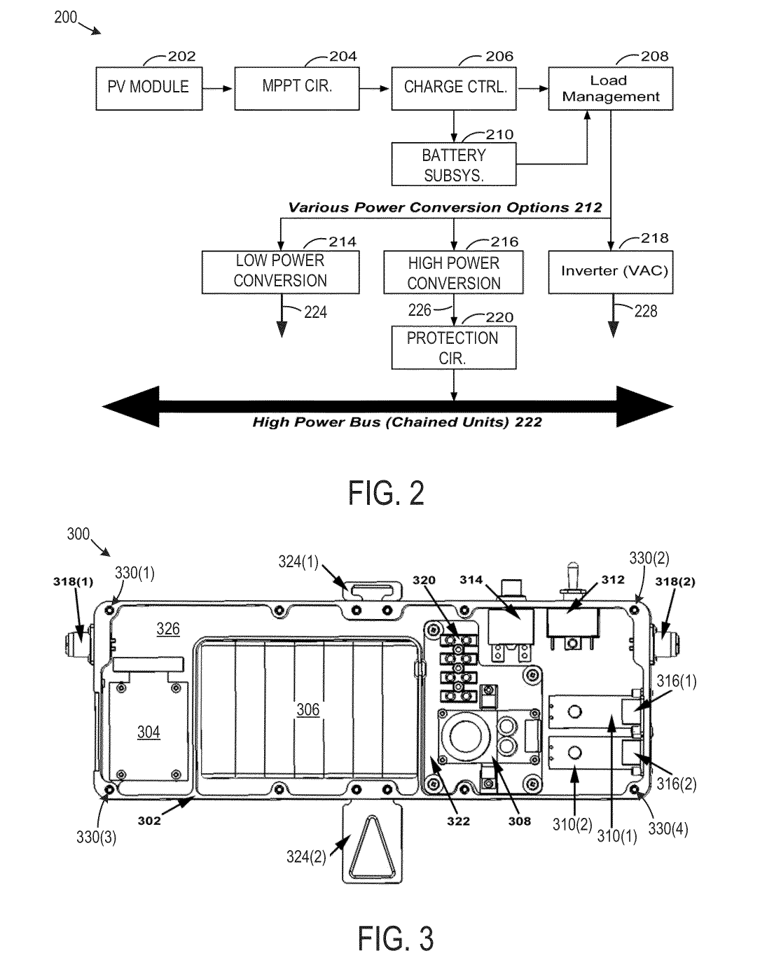

In order to decouple these functions effectively, it is necessary that the portable PV power system (1) includes a battery storage subsystem that provides the bulk of the electrical power to a load, (2) provides power for charging the battery subsystem, and (3) is capable of simultaneously providing power from the photovoltaic device and battery subsystem to the load. FIG. 2 is a block diagram of a photovoltaic-based fully integrated portable power system 200 that not only encompasses all of the functions noted above, but also is capable of forming a lightweight, compact system.

Portable power system 200 includes a flexible PV module 202, maximum power point tracking circuitry 204, charge control circuitry 206, load management circuitry 208, a battery subsystem 210, low power conversion circuitry 214, high power conversion circuitry 216, an inverter 218, and protection circuitry 220. As further discussed below, maximum power point tracking circuitry 204, charge control circuitry 206, load management circuitry 208, battery subsystem 210, low power conversion circuitry 214, high power conversion circuitry 216, inverter 218, and protection circuitry 220 are co-packaged, optionally with additional components (not shown), in an integrated power management, storage, and distribution (MSD) subsystem.

Flexible PV module 202 includes a plurality of PV cells for converting light, such as sunlight, into electricity. The PV cells are electrically coupled in series and/or in parallel, to obtain a desired output voltage and output current capability. In some embodiments, flexible PV module 202 includes a plurality of electrically interconnected flexible PV submodules monolithically integrated onto a common flexible substrate. Each PV submodule, in turn, includes a plurality of electrically interconnected flexible thin-film PV cells monolithically integrated onto the flexible substrate. The PV cells of flexible PV module 202 include, for example, copper-indium-gallium-selenide (CIGS) PV cells, copper-indium-gallium-sulfur-selenide (CIGSSe) PV cells, copper zinc tin sulfide (CZTS) PV cells, cadmium-telluride (CdTe) PV cells, silicon (Si) PV cells, and/or amorphous silicon (a-Si) PV cells. In some other embodiments, the PV cells of flexible PV module 202 include flexible crystalline PV cells, such as a thin crystalline silicon (Si) photovoltaic cells or thin gallium arsenide (GaAs) photovoltaic cells. The flexible crystalline PV cells are for example fabricated by epitaxial lift-off (ELO) or by mechanical thinning of crystalline wafers, in these embodiments.

Flexible PV module 202 is electrically coupled to MPPT circuitry 204 which automatically adjusts its input impedance to ensure that flexible PV module 202 operates at its maximum power point. The output of MPPT circuitry 204 is electrically coupled to charge control circuitry 206 which that monitors the voltage of battery subsystem 210. Possible functions of charge control circuitry 206 include (1) determining the charge state of battery subsystem 210, routing power from flexible photovoltaic module 202 to battery subsystem 210 to safely charge battery subsystem 210 if it is not sufficiently charged, (3) terminating charging of battery subsystem 210 when it has reached its maximum capacity, and/or (4) routing power from flexible photovoltaic module 202, that is not associated with charging of battery subsystem 210, to load management circuitry 208. In addition, charge control circuitry 206 may monitor the health of the battery subsystem 210, preventing the charging of batteries of battery subsystem 210 that are damaged or have exceeded their useful life. In some embodiments, battery subsystem 210 includes one or more lithium ion (LiIon) batteries, lithium polymer (LiPo) batteries, lithium iron phosphate (LiFePO₄) batteries, or zinc-air batteries.

Load management circuitry 208 converts power received from charge control circuitry 206 and/or from battery subsystem 210 into a stable, fixed DC power output on an internal bus voltage rail 212 for use by various power conversion options. Load management circuitry 208 also provides overcurrent protection on internal bus voltage rail 212, in some embodiments. Low power conversion circuitry 214 generates a low power voltage rail 224 from internal bus voltage rail 212, such as for charging portable electronic devices through one or more USB interfaces (not shown) electrically coupled to low power voltage rail 224. In some embodiments, the USB interfaces support 1.x, 2.x and 3.x protocols. For portable power systems, the USB interface is desirable as it is the de facto battery charging interface for cell phones, MP3 players, tablets, and various other portable electronic devices.

High power conversion circuitry 216 generates a high power voltage rail 226 from internal bus voltage rail 212. The voltage of high power voltage rail 226 is user-selectable in some embodiments. High power voltage rail 226 is electrically coupled to a high power bus 222 in certain embodiments via protection circuitry 220. High power voltage rail 226 is used, for example, to operate larger electronic devices, or even to chain to similar PV portable power systems in parallel through high power bus 222. For example, in some embodiments, high power conversion circuitry 216 is capable of generating high power voltage rail 226 at a voltage of 24 VDC, such as for use by the military and first responders. Additionally, two or more instances of portable power system 200 could be electrically coupled in parallel via high power bus 222, to power large loads.

Inverter 218 generates an AC output 228 from internal bus voltage rail 212, such as for operating common household equipment. Inverter 218 is, for example, matched to the voltage and frequency of its intended load (e.g., 120 VAC at 60 hertz or 220 VAC at 50 hertz). In embodiments intended to power large AC loads, flexible photovoltaic module 202, MPPT circuitry 204, charge control circuitry 206, load management circuitry 208, battery subsystem 210, and inverter 218 must be capable of supporting such load.

Low power conversion circuitry 214, high power conversion circuitry, and inverter 218 are each electrically coupled to one or more electrical connectors for interfacing with external circuitry. The electrical connectors include two leads providing positive and negative terminals, respectively. In certain embodiments, the electrical connectors are waterproof and capable of preventing moisture ingress into a case of the MSD subsystem. The electrical connectors are optionally automotive-grade or military grade to promote reliability and long life. In a particular embodiment, one or more of the electrical connectors are magnetically-attached connectors.

In some embodiments, MPPT circuitry 204, charge control circuitry 206, and load management circuitry 208 are integrated into a single component. Low power conversion circuitry 214, high power conversion circuitry 216, and inverter 218 are also integrated into a single component in certain embodiments. Furthermore, it should be appreciated that the number and configuration of devices electrically coupled to internal bus voltage rail 212 may be varied without departing from the scope hereof. For example, one or more of low power conversion circuitry 214, high power conversion circuitry 216, and inverter 218 could be omitted. As another example, additional power conversion circuitry could be electrically coupled to internal bus voltage rail 212.

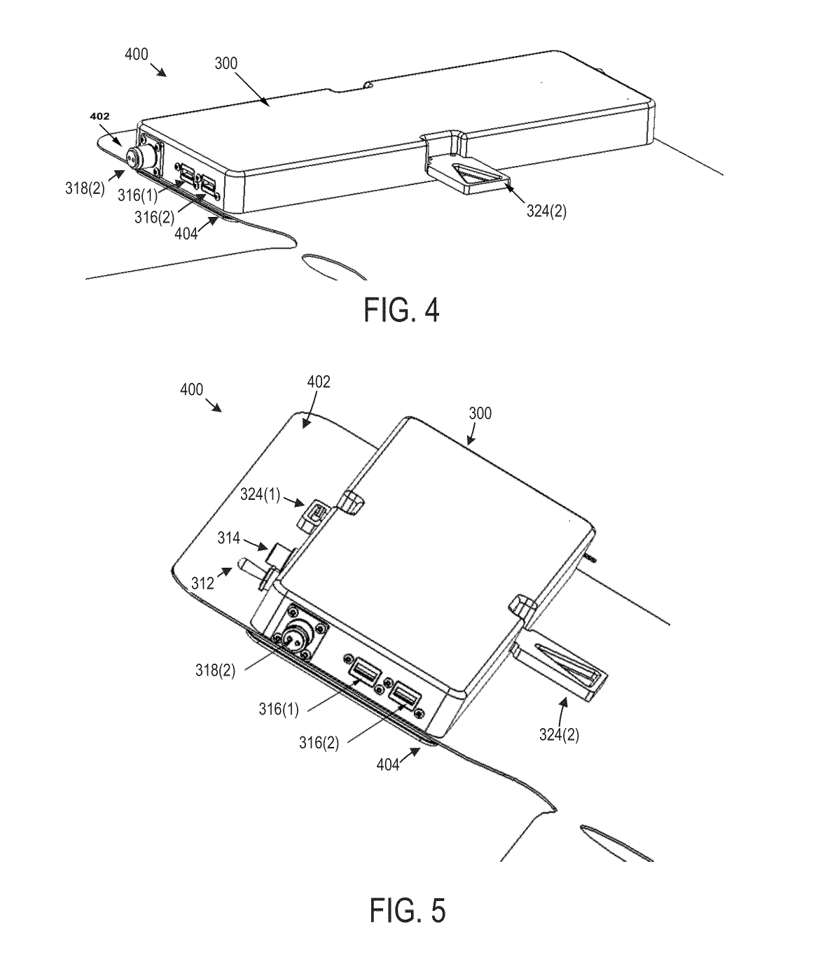

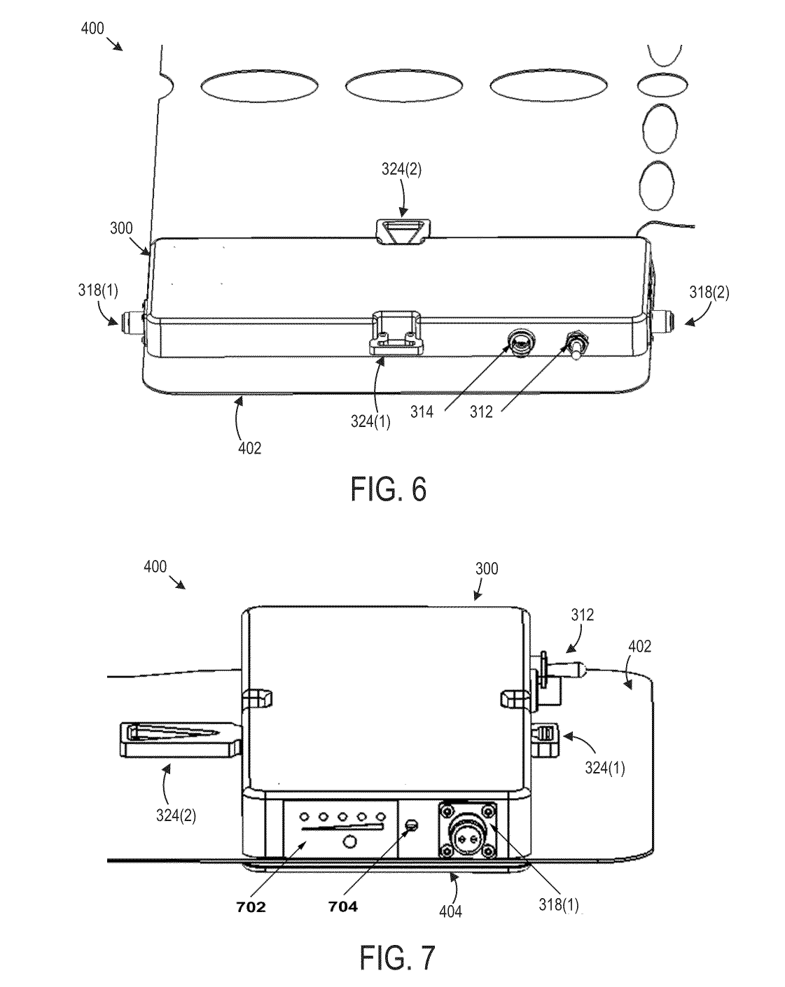

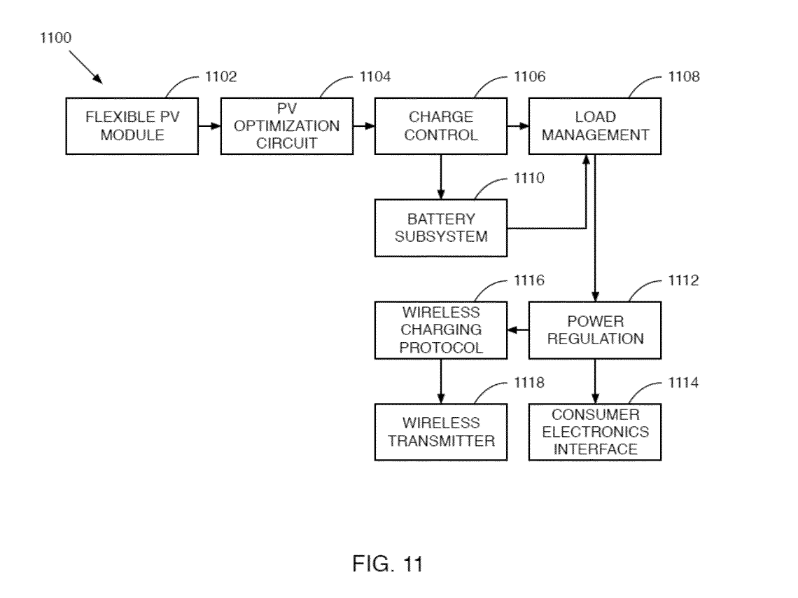

FIG. 3 is a top plan view of a MSD subsystem 300, which is one possible embodiment of the MSD subsystem of portable power system 200. FIG. 10 is an exploded perspective view of a MSD subsystem 300 along with an associated mounting plate 404 and gasket 1002. MSD subsystem 300 includes maximum power point tracking circuitry, charge control circuitry, load management circuitry, a battery subsystem, low power conversion circuitry, high power conversion circuitry, an inverter, and protection circuitry co-packaged in a common case 302. In some embodiments, case 302 is rigid, impervious to moisture, capable of minimizing ingress of water into the case through openings, and/or a ruggedized case capable of withstanding significant impact and physical abuse. Case 302 is, for example, formed of lightweight, non-metallic material, which in some embodiments, is formed by machining, molding, or 3-D printing. Case 302 has an opening 326 which interfaces with a flexible photovoltaic module. In particular, gasket 1002 is disposed in opening 326, a portion of a flexible photovoltaic module (not shown in FIGS. 3 and 10) is disposed on opening 326 over gasket 1002, and mounting plate 404 is disposed on the flexible photovoltaic module over opening 326, such that a portion of the flexible photovoltaic module is sandwiched between MSD subsystem 300 and mounting plate 404, as discussed below with respect to FIGS. 4-7. Mounting plate 404 is affixed to case 302 via fasteners 1004 (see FIG. 10). Only some instances of fasteners 1004 are labeled in FIG. 10 to promote illustrative clarity.

The functions of MPPT circuitry 204, charge control circuitry 206, and load management circuitry 208 are combined into an MPPT system board 304 in MSD subsystem 300. MPPT system board 304 is matched to the voltage and chemistry of a lightweight battery subsystem 306, which implements battery subsystem 210. Additionally, the output voltage of MPPT system board 304 is matched to input voltage required by high power regulator board 308 and the low power USB regulator boards 310, which respectively implement high power conversion circuitry 216 and low power conversion circuitry 214. Protection circuitry 220 is implemented via a power disconnect switch 312 and a pop-open circuit breaker 314 which opens when load magnitude exceeds rated specifications. In some embodiments, protection circuitry 220 is further implemented via at least one fuse (not shown) triggered by excessive current magnitude. To achieve moisture ingress protection, disconnect switch 312, circuit breaker 314, and fuse holders (if applicable) are typically waterproof, and in some embodiments, these components are rugged and/or meet automotive or military specifications. In an alternate embodiment, disconnect switch 312 is replaced with, or supplemented by, a magnetically-keyed switch activated through case 302, or a wirelessly operated disconnect switch, for disconnecting MSD subsystem 300 from external circuitry.

To provide electrical power to a user, waterproof USB connectors 316 are electrically coupled to outputs of respective low power USB regulator boards 310, and high-power waterproof connectors 318 are electrically coupled to an output of high power regulator board 308. In a particular embodiment, connectors 318(1) and 318(2) are connected in parallel to high power bus 222, thereby enabling a high-power pass-through, or bus, to similar systems connected to each of them. Disconnect switch 312 and circuit breaker 314 provide isolation from high-power bus 222. Connectors 318 are military grade in some embodiments to be certifiable in such applications. MSD subsystem 300 further includes a terminal strip 320 to provide connection points among the various power connections within MSD subsystem 300. In some embodiments, terminal strip 320 includes, but not limited to, connections to the output bus voltage from MPPT system board 304, as well as to high-power bus 222.

MSD subsystem 300 optionally further includes a heat spreader 322 thermally coupled to high power regulator board 308 to transfer heat away from the regulator board. Use of heat spreader 322 may be desired, for example, in embodiments where thermal conductivity of case 302 is insufficient to adequately cool high power regulator board 308. Heat spreader 322 is typically formed of a material that has a high thermal conductivity and is light weight, such as aluminum or carbon-carbon composite materials.

MSD subsystem 300 further includes at least one strap connector 324 disposed on an exterior of case 302. As further discussed below, strap connectors 324 are capable of at least partially securing a flexible photovoltaic module to MSD subsystem 300, when the flexible photovoltaic module is placed in a folded position for stowing.

Case 302 is optionally potted to protect circuitry and wiring therein from damage from moisture, dirt, and vibration. In some embodiments, case 302 also provides a rugged mounting point for various accessories.

FIGS. 4-7 each show a different perspective view of a photovoltaic-based fully integrated portable power system 400, which is an embodiment of portable power system 200 (FIG. 2). Portable power system 400 includes an instance of MSD subsystem 300 attached to a flexible photovoltaic module 402 implementing flexible photovoltaic module 202. Specifically, a portion of flexible photovoltaic module 402 is disposed on opening 326 (not visible in FIGS. 4-7) in case 302 of MSD subsystem 300, and mounting plate 404 is disposed on flexible photovoltaic module 402 over opening 326, such that a portion of flexible photovoltaic module 402 is sandwiched between MSD subsystem 300 and mounting plate 404. See, for example, FIGS. 4, 5, and 7. Consequentially, opening 326 is covered by a portion of flexible photovoltaic module 402 and mounting plate 404. Dimensions of the mounting plate 404 may exceed that of the case 302 in order to add necessary stiffness to protect from damage during repeated deployment and stowage operations. Fastening devices 1004, such as screws, bolts, or rivets, secure mounting plate 404 to MSD subsystem 300, as discussed above. For example, in a particular embodiment, screws, bolts, or rivets extend at least from mounting plate 404 to mounting holes 330 in case 302, to secure mounting plate 404 to MSD subsystem 300. Only some instances of mounting holes 330 are labeled in FIG. 3 to promote illustrative clarity.

Flexible photovoltaic module 402 includes electrical terminals electrically coupled to MSD subsystem 300. The electrical terminals are covered by MSD subsystem 300, and in some embodiments, the electrical terminals are further covered by mounting plate 404, to help prevent accidental contact to the electrical terminals and to protect the electrical terminals from possible impact damage. Flexible photovoltaic module 402 is capable of being disposed in at least an unfolded position for deployment and in a folded position for stowing. Strap connectors 324 are capable of securing flexible photovoltaic module 402 to MSD subsystem 300 when flexible photovoltaic module 402 is disposed in its folded position.

USB connectors 316, high-power connector 318(2), and strap connector 324(2) are visible in the FIG. 4 perspective view. Disconnect switch 312, circuit breaker 314, strap connector 324(1) are further visible in the FIG. 5 perspective view, and both high power connectors 318 are visible in the FIG. 6 perspective view. A battery status display 702 and an indicator 704 are visible in the perspective view of FIG. 7, and battery status display 702 is visible in the perspective view of FIG. 10. Battery status display 702 alerts a user as to the charge state of battery subsystem 306. Although battery status display 702 is illustrated as being implemented by a plurality of light emitting diodes (LEDs), the battery status display may alternately be implemented by an electromechanical meter or a digital display. Indicator 704 alerts a user as to the MPPT status of MSD 300, such as MPPT performance, including whether the battery is being charged, if the battery system is faulty, or if the load is excessive. In some embodiments, indicator 704 also alerts a user if flexible PV module 402 has sunlight available to it and disconnect switch 312 has disabled the system (e.g. battery subsystem 306 is not charging). When portable power system 400 is inverted so that the light sensitive side of flexible PV module 402 is facing towards the sun, USB connectors 316, high power connectors 318, disconnect switch 312, and circuit breaker 314 are still accessible from the side.

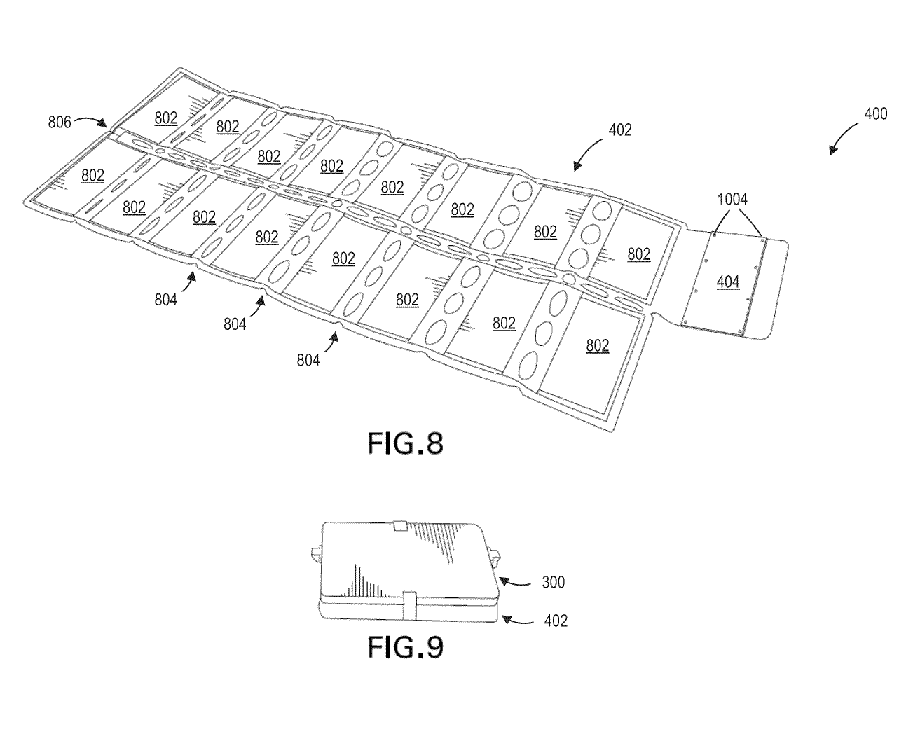

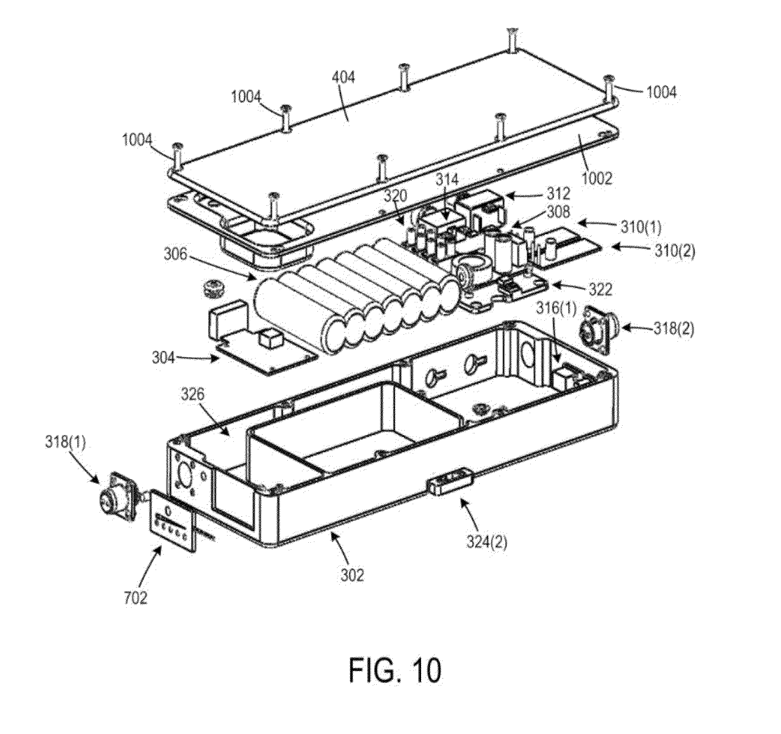

FIG. 8 illustrates one embodiment of portable power system 400 with flexible photovoltaic module 402 in its unfolded (deployed) position, and FIG. 9 illustrates this embodiment with flexible photovoltaic module 402 in its folded (stowed) position. MSD subsystem 300 is under flexible PV module 402 when the flexible PV module is in its unfolded/deployed position, so that MSD subsystem 300 does not block the light sensitive side of flexible PV module 402. Flexible photovoltaic module 402 includes a plurality of photovoltaic submodules 802 joined by hinges 804 and 806. Only some instances of hinges 804 are labeled to promote illustrative clarity. Hinges 804 and 806 are, for example, subtractive hinges, as illustrated. As discussed in U.S. Patent Application Publication No. 2013/0228209 to Messing, which is incorporated herein by reference, subtractive hinges advantageously achieve a stiffness differential by removing portions of the hinge material, instead of by adding stiffening material to the coupled sections.

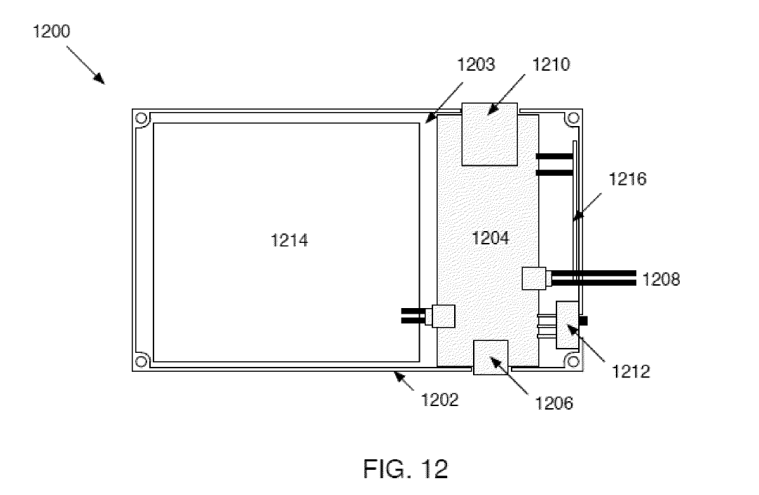

Applicant has further developed pocket-sized photovoltaic-based fully integrated portable power systems including MPPT circuitry. For example, FIG. 11 is a block diagram of a pocket-sized photovoltaic-based fully integrated portable power system 1100 including a flexible PV module 1102 similar to flexible PV module 202 of portable power system 200, MPPT circuitry 1104, charge control circuitry 1106, load management circuitry 1108, a battery subsystem 1110 similar to battery subsystem 210 of portable power system 200, power regulation 1112, and a CE charging interface 1114. Optionally, wireless charging can be facilitated by a wireless charging protocol circuit 1116, and a matching wireless transmitter 1118 can be used for wirelessly charging CE devices. As further discussed below, MPPT circuitry 1104, charge control circuitry 1106, load management circuitry 1108, battery subsystem 1110, power regulation 1112, CE interface 1114, and wireless charging protocol 1116 with matching wireless transmitter 1118 are co-packaged, possibly along with additional components, in an integrated MSD subsystem.

Flexible photovoltaic module 1102 is electrically coupled to MPPT circuitry 1104 which passively or dynamically adjusts its input impedance to ensure that flexible PV module 1102 operates at its maximum power point. The output of MPPT circuitry 1104 is electrically coupled to charge control circuitry 1106 which monitors the voltage of battery subsystem 1110. Possible functions of charge control circuitry 1106 include (1) determining the charge state of battery subsystem 1110, routing power from flexible photovoltaic module 1102 to battery subsystem 1110 to safely charge battery subsystem 1110 if it is not sufficiently charged, (3) terminating charging of battery subsystem 1110 when it has reached its maximum capacity, and/or (4) routing power from flexible photovoltaic module 1102, that is not associated with charging of battery subsystem 1110, to load management circuitry 1108. In addition, charge control circuitry 1106 may monitor the health of the battery subsystem 1110, preventing the charging of batteries that are damaged or have exceeded their useful life. In some embodiments, battery subsystem 1110 includes one or more lithium ion (LiIon) batteries, lithium polymer (LiPo) batteries, lithium iron phosphate (LiFePO₄), or zinc-air batteries.

Load management circuitry 1108 converts power received from charge control circuitry 1106 and/or from battery subsystem 1110 into a stable, fixed DC power output for use by various charging options. Load management circuitry 1108 also provides overcurrent protection with regard to the power regulation circuit 1112, in some embodiments. In one embodiment, power regulation 1112 provides power to CE interface 1114, such as for charging portable electronic devices through one or more USB interfaces. In some embodiments, CE interface 1114 supports USB 1.x, 2.x and 3.x protocols. For portable power systems servicing the CE devices, the USB interface is necessary as it is the de facto battery charging interface for cell phones, MP3 players, tablets, and various other portable electronic devices.

In certain embodiments, a wireless means for charging CE devices is facilitated by wireless charging protocol circuit 1116 coupled to matching wireless transmitter 1118. In some embodiments the wireless charging protocol can represent RF charging or inductive charging. In some embodiments this wireless charging protocol may represent a commercial standard such as Qi or other ubiquitous wireless charging solutions.

In some embodiments, MPPT circuitry 1104, charge control circuitry 1106, load management circuitry 1108, power regulation 1112 and CE interface 1114 are integrated into a single component. Wireless charging protocol circuitry 1116 and transmitter 1118 may also be integrated into a single component in certain embodiments, and possibly further integrated with the component noted earlier.

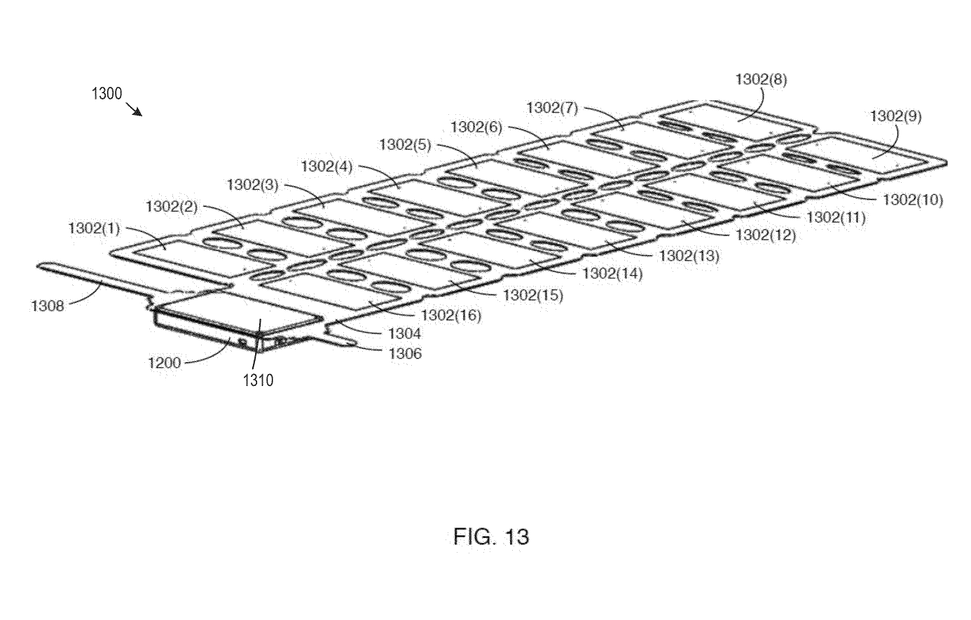

FIG. 12 is a top plan view of a MSD subsystem 1200, which is one possible embodiment of the MSD subsystem of portable power system 1100. Accordingly, MSD subsystem 1200 includes peak power tracking circuitry, either passive or dynamic in nature, charge control circuitry, MPPT circuitry, a battery subsystem, power regulation, CE interfaces co-packaged in a common case 1202. In some embodiments, case 1202 is rigid, impervious to moisture, capable of minimizing ingress of water into the case through openings, and/or a ruggedized case capable of withstanding significant impact and physical abuse. Case 1202 is, for example, formed of lightweight, non-metallic material, which in some embodiments, is formed by machining, molding, or 3-D printing. Case 1202 has an opening 1203 on the side that interfaces with a flexible photovoltaic module to facilitate connections between the MSD 1200 and flexible PV module 1102, in a manner similar to that discussed above with respect to portable power system 400. In particular, a portion of flexible photovoltaic module 1102 is disposed over opening 1203, and a mounting plate is disposed over opening 1203, such that the portion of flexible photovoltaic module 1102 is sandwiched between MSD subsystem 1200 and the mounting plate.

The functions of MPPT circuitry 1104, charge control circuitry 1106, load management circuitry 1108, and power regulation 1112 are combined into a single system board 1204 in MSD subsystem 1200. The system board 1204 is matched to the voltage and chemistry of a lightweight battery subsystem 1214, which implements battery subsystem 1110. Power to charge the battery subsystem 1214 is provided by either leads 1208 from flexible PV module 1102, or from an external power supply interfacing through a USB input 1206. A power switch 1212 controls the on-off state of a USB interface 1210 that connects to a CE device for charging. To achieve moisture ingress protection, disconnect switch 1212 and USB interfaces 1206 and 1210 may either be inherently waterproof, or in some embodiments, achieve a waterproof state by a detachable water-tight cover over each of the components.

Case 1202 is optionally potted to protect circuitry and wiring therein from damage from moisture, dirt, and vibration. In some embodiments, case 1202 also provides a rugged mounting point for various accessories.

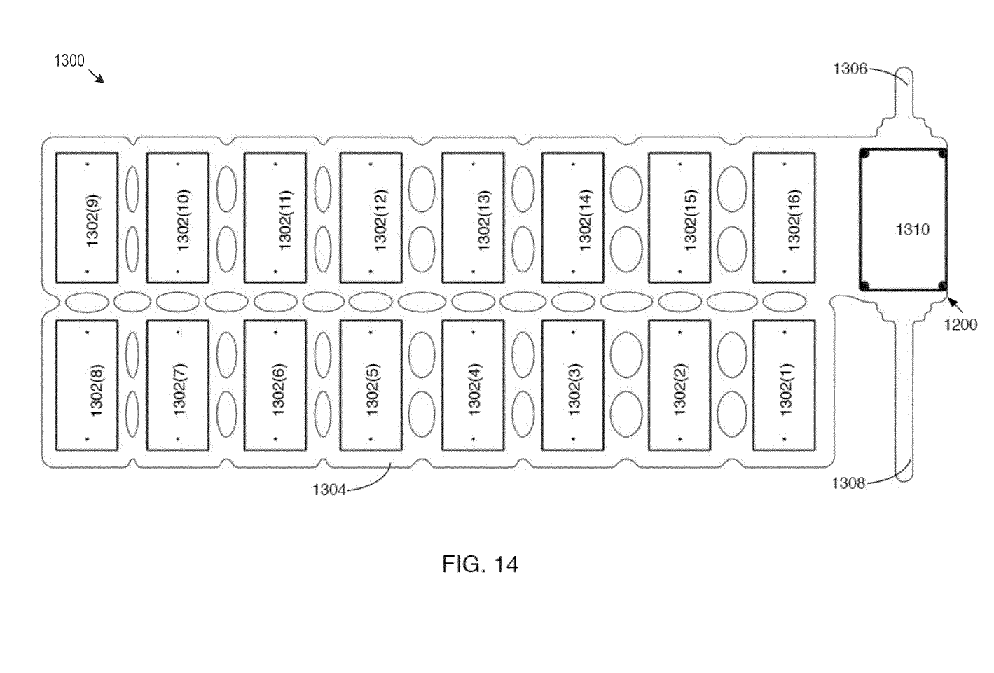

FIG. 13 is a perspective view of an assembled pocket-sized fully integrated portable system 1300, which is an embodiment of pocket-sized photovoltaic-based fully integrated portable power system 1100 of FIG. 11 incorporating MSD subsystem 1200 of FIG. 12. A plurality of PV submodules 1302 are integrated into a single folding PV blanket 1304, which is an embodiment of flexible photovoltaic module 1102. PV blanket 1304 may further include laminate and fabric to facilitate the proper folding and stowage. In this embodiment, PV blanket 1304 utilizes a subtractive hinge approach to define fold lines. In this embodiment, sixteen (16) PV submodules 1302 are electrically interconnected to mounted MSD subsystem 300. In this embodiment, integrated straps 1306 and 1308 are formed during the fabrication process of PV blanket 1304 and include a restraining system that confines the folding PV blanket 1304 when in its stowed configuration. These straps may be connected by hook-and-loop elements, mechanical snaps, or mechanical snaps, for example. A portion of PV blanket 1304 is disposed over opening 1203 (not visible in FIG. 13) in MSD 1200, and a mounting plate 1310 is disposed over opening 1203, such that the portion of PV blanket 1304 is sandwiched between MSD subsystem 1200 and mounting plate 1310.

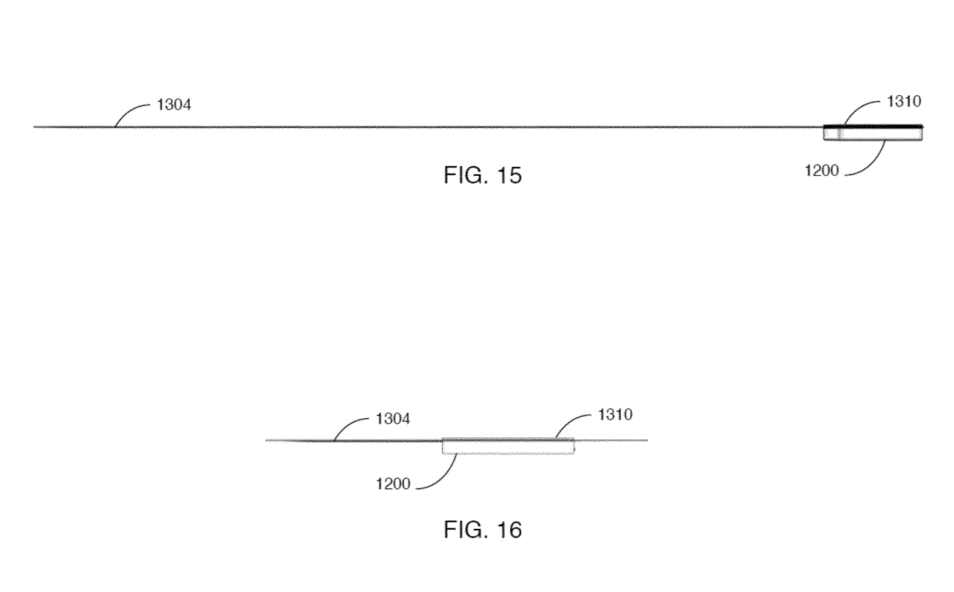

FIGS. 14, 15, and 16 illustrate a top, side, and end view, respectively, of pocket-sized photovoltaic-based fully integrated portable system 1300 in its deployed state.

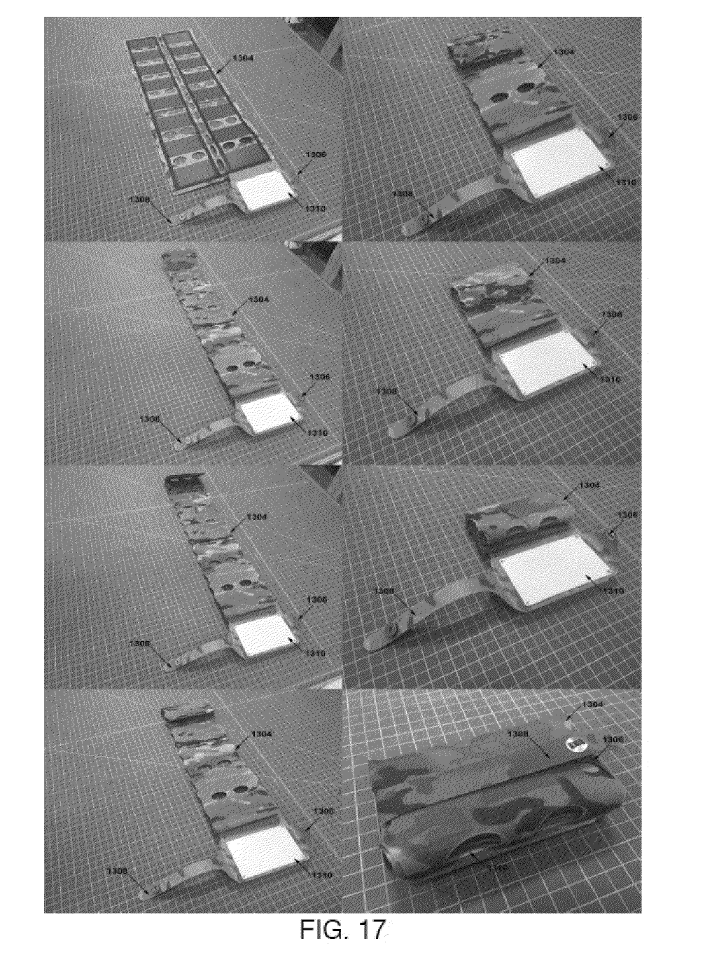

FIG. 17 contains a sequence of photographs that illustrate one embodiment of the deployment and stowage of pocket-sized photovoltaic-based fully integrated portable system 1300. When deployed, all PV elements are available for exposure to sunlight, and MSD 1200 is available to connect to a desired CE device.

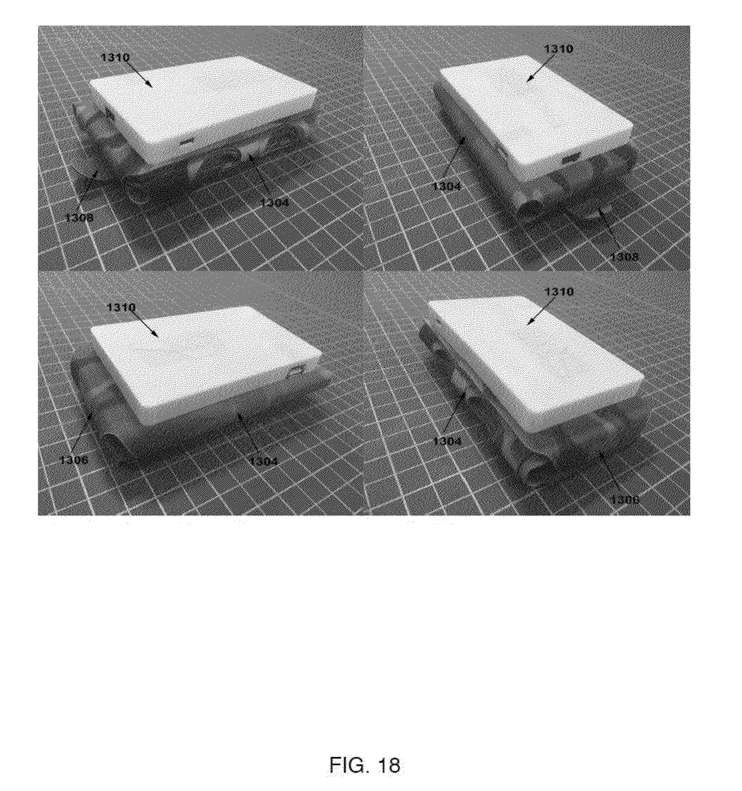

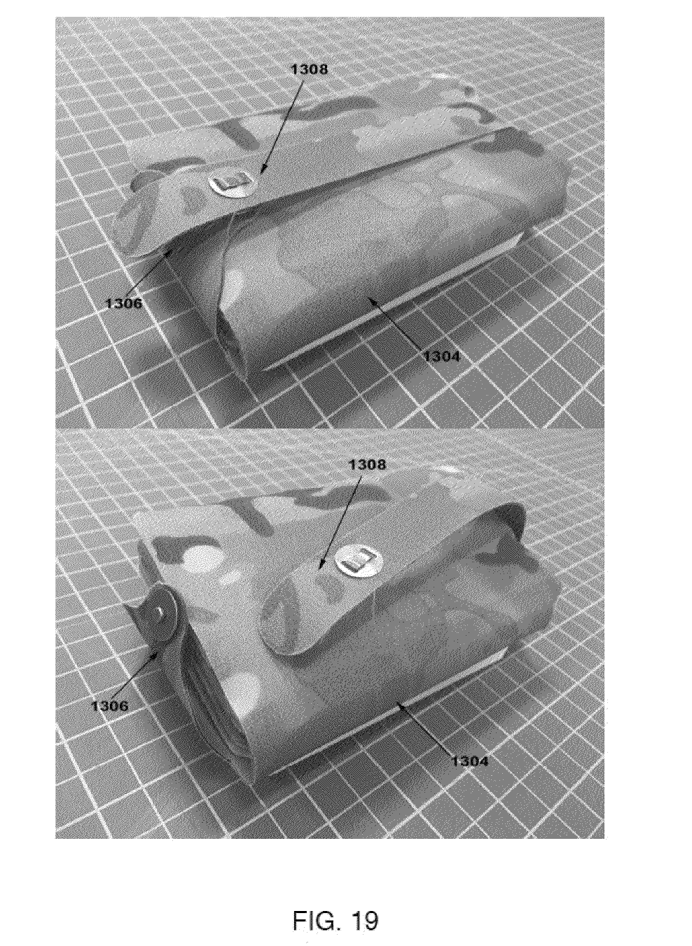

FIG. 18 contains photographs of four views of one embodiment of pocket-sized photovoltaic-based fully integrated portable system 1300. FIG. 19 contains photographs of the bottom of pocket-sized photovoltaic-based fully integrated portable system 1300, illustrating the restraining system consisting of straps 1306 and 1308. In this embodiment, capture of the two strap elements is facilitated by a magnetic clasp.

Combinations of Features

Features described above as well as those claimed below may be combined in various ways without departing from the scope hereof. The following examples illustrate some possible combinations:

(A1) A photovoltaic-based fully integrated portable power system may include (1) an integrated power management, storage, and distribution (MSD) subsystem including a case having an opening, (2) a flexible photovoltaic module, and (3) a mounting plate. The flexible photovoltaic module may be capable of being disposed in at least a folded position and an unfolded position, and a portion of the flexible photovoltaic module may be disposed over the opening of the case. The mounting plate may be disposed on the flexible photovoltaic module and over the opening of the case, such that the portion of the flexible photovoltaic module is sandwiched between the MSD subsystem and the mounting plate.

(A2) The system denoted as (A1) may further include at least one strap connector for securing the flexible photovoltaic module to the MSD subsystem when the flexible photovoltaic module is disposed in the folded position.

(A3) In the system denoted as (A1), the MSD subsystem may include at least one strap connector for securing the flexible photovoltaic module to the MSD subsystem when the flexible photovoltaic module is disposed in the folded position.

(A4) In any of the systems denoted as (A1) through (A3), the flexible photovoltaic module may include electrical terminals covered by at least the MSD subsystem.

(A5) In any of the systems denoted as (A1) through (A4), the mounting plate may extend beyond a perimeter of the case.

(A6) In any of the systems denoted as (A1) through (A5), the flexible photovoltaic module may include at least one flexible thin-film photovoltaic device selected from the group consisting of a copper-indium-gallium-selenide (CIGS) photovoltaic device, a copper-indium-gallium-sulfur-selenide (CIGSSe) photovoltaic device, a copper zinc tin sulfide (CZTS) photovoltaic device, a cadmium-telluride (CdTe) photovoltaic device, a silicon (Si) photovoltaic device, and an amorphous silicon (a-Si) photovoltaic device.

(A7) In any of the systems denoted as (A1) through (A5), the flexible photovoltaic module may include at least one flexible crystalline photovoltaic device selected from the group consisting of a thin crystalline silicon (Si) photovoltaic device and a thin gallium arsenide (GaAs) photovoltaic device.

(A8) In the system denoted as (A7), the at least one flexible crystalline photovoltaic device may be fabricated by epitaxial lift-off (ELO) or by mechanical thinning of crystalline wafers.

(A9) In any of the systems denoted as (A1) through (A8), the MSD subsystem may include a ruggedized case for providing protection from physical and environmental attack, as well as mechanical mounting points for internal circuitry and through access for electrical connectors and indicators.

(A10) In any of the systems denoted as (A1) through (A9), the MSD subsystem may include (1) maximum power point tracking circuitry for causing the flexible photovoltaic module to operate at its maximum power point, (2) charge control circuitry for controlling charging of a battery subsystem, (3) load management circuitry for generating an internal bus voltage rail and for providing overcurrent protection, (4) low power conversion circuitry for generating a low power voltage rail from the internal bus voltage rail, (5) high power conversion circuitry for generating a high power voltage rail from the internal bus voltage rail, and (6) protection circuitry for interrupting operation of the MSD subsystem and disconnecting the MSD subsystem from external circuitry.

(A11) The system denoted as (A10) may further include an inverter.

(A12) Either of systems denoted as (A10) or (A11) may further include the battery subsystem, and the battery subsystem may include a battery selected from the group consisting of a lithium ion (LiIon) battery, a lithium polymer (LiPo) battery, a lithium iron phosphate (LiFePO₄) battery, and a zinc-air battery.

(A13) In any of the systems denoted as (A10) through (A12), the protection circuitry may include at least one fuse triggered by excessive current magnitude.

(A14) In the system denoted as (A13), the MSD subsystem may include a fuse holder for housing the at least one fuse, and the fuse holder may be capable of preventing moisture ingress into the case of the MSD subsystem.

(A15) In any of the systems denoted as (A10) through (A14), the protection circuitry may include a user-resettable circuit breaker triggered by excessive current magnitude.

(A16) In the system denoted as (A15), the user-resettable circuit breaker may be capable of preventing moisture ingress into a case of the MSD subsystem.

(A17) In any of the systems denoted as (A10) through (A16), the protection circuitry may include a mechanical disconnect switch for disconnecting the MSD subsystem from external circuitry.

(A18) In the system denoted as (A17), the mechanical disconnect switch may be capable of preventing moisture ingress into the case of the MSD subsystem.

(A19) In any of the systems denoted as (A10) through (A18), the protection circuitry may include a magnetically-keyed switch activated through the case of the MSD subsystem, for disconnecting the MSD subsystem from external circuitry.

(A20) In any of the systems denoted as (A10) through (A19), the protection circuitry may include a wirelessly operated disconnect switch, for disconnecting the MSD subsystem from external circuitry.

(A21) In any of the systems denoted as (A1) through (A9), the MSD subsystem may include (1) maximum power point tracking circuitry for causing the flexible photovoltaic module to operate at or near its maximum power point, (2) a battery subsystem for storing and providing electrical power, (3) charge control circuitry for controlling charging of the battery subsystem, (4) load management circuitry for generating an internal bus voltage rail and for providing overcurrent protection, (5) power regulation circuitry to provide power for operating and charging external devices, and (6) consumer electric-based electrical interfaces for transmitting stored power to external devices.

(A22) In the system denoted as (A21), the maximum power point tracking circuitry may be selected from the group consisting of dynamic maximum power point tracking circuitry and passive maximum power point tracking circuitry.

(A23) Any of the systems denoted as (A10) through (A22) may further include at least one electrical connector for interfacing with external circuitry.

(A24) In the system denoted as (A23), the at least one electrical connector may include an USB interface with 1.x, 2.x and 3.x protocols.

(A25) In either of the systems denoted as (A23) or (A24), the at least one electrical connector may be waterproof.

(A26) In any of the systems denoted as (A23) through (A25), the at least one electrical connector may be capable of preventing moisture ingress into a case of the MSD subsystem.

(A27) In any of the systems denoted as (A23) through (A26), the at least one electrical connector may include an automotive-grade connector.

(A28) In any of the systems denoted as (A23) through (A27), the at least one electrical connector may include a threaded military-grade connector.

(A29) In any of the systems denoted as (A23) through (A28), the at least one electrical connector may include two leads providing high power positive and negative terminals, respectively.

(A30) In any of the systems denoted as (A23) through (A29), the at least one electrical connector may include first and second electrical connectors electrically coupled in parallel, for providing an internal bypass for stringing multiple systems together to increase power capacity.

(A31) In any of the systems denoted as (A23) through (A30), the at least one electrical connector may include a magnetically-attached connector.

(A32) Any of the systems denoted as (A1) through (A31) may further include circuitry for providing external power for charging the battery subsystem in lieu of the flexible photovoltaic module.

(A33) Any of the systems denoted as (A1) through (A32) may further include a wireless charging protocol circuit coupled to a matching wireless transmitter for wireless power transmission to an external device.

Changes may be made in the above apparatus, systems and methods without departing from the scope hereof. For example, flexible photovoltaic module 402 could be replaced with another electrical power source, such as a wind turbine or a fuel cell, without departing from the scope hereon. Therefore, it is intended that all matter contained in the above description or shown in the accompanying drawings be interpreted as illustrative and not in a limiting sense. It is also to be understood that the following claims are to cover certain generic and specific features described herein.

What is claimed is:

1. A photovoltaic-based fully integrated portable power system, comprising:
an integrated power management, storage, and distribution (MSD) subsystem including a case having an opening;
a flexible photovoltaic module capable of being disposed in at least a folded position and an unfolded position, a portion of the flexible photovoltaic module being disposed over the opening of the case; and
a mounting plate disposed on the flexible photovoltaic module and over the opening of the case, such that the portion of the flexible photovoltaic module is sandwiched between the MSD subsystem and the mounting plate.

2. The system of claim 1, the MSD subsystem comprising at least one strap connector for securing the flexible photovoltaic module to the MSD subsystem when the flexible photovoltaic module is disposed in the folded position.

3. The system of claim 1, the flexible photovoltaic module including electrical terminals covered by at least the MSD subsystem.

4. The system of claim 1, the mounting plate extending beyond a perimeter of the case.

5. The system of claim 1, the flexible photovoltaic module comprising at least one flexible thin-film photovoltaic device selected from the group consisting of a copper-indium-gallium-selenide (CIGS) photovoltaic device, a copper-indium-gallium-sulfur-selenide (CIGSSe) photovoltaic device, a copper zinc tin sulfide (CZTS) photovoltaic device, a cadmium-telluride (CdTe) photovoltaic device, a silicon (Si) photovoltaic device, and an amorphous silicon (a-Si) photovoltaic device.

6. The system of claim 1, the flexible photovoltaic module comprising at least one flexible crystalline photovoltaic device selected from the group consisting of a thin crystalline silicon (Si) photovoltaic device and a thin gallium arsenide (GaAs) photovoltaic device.

7. The system of claim 1, the MSD subsystem comprising a ruggedized case for providing protection from physical and environmental attack, as well as mechanical mounting points for internal circuitry and through access for electrical connectors and indicators.

8. The system of claim 1, the MSD subsystem comprising:
maximum power point tracking circuitry for causing the flexible photovoltaic module to operate at its maximum power point;
charge control circuitry for controlling charging of a battery subsystem;
load management circuitry for generating an internal bus voltage rail and for providing overcurrent protection;
low power conversion circuitry for generating a low power voltage rail from the internal bus voltage rail;
high power conversion circuitry for generating a high power voltage rail from the internal bus voltage rail; and
protection circuitry for interrupting operation of the MSD subsystem and disconnecting the MSD subsystem from external circuitry.

9. The system of claim 8, the MSD subsystem further comprising an inverter.

10. The system of claim 8, the MSD subsystem further comprising the battery subsystem, the battery subsystem including a battery selected from the group consisting of a lithium ion (LiIon) battery, a lithium polymer (LiPo) battery, a lithium iron phosphate (LiFePO₄) battery, and a zinc-air battery.

11. The system of claim 1, the MSD subsystem further comprising at least one electrical connector for interfacing with external circuitry.

12. The system of claim 11, the at least one electrical connector comprising an USB interface with 1.x, 2.x and 3.x protocols.

13. The system of claim 11, the at least one electrical connector being waterproof.

14. The system of claim 11, the at least one electrical connector comprising two leads providing high power positive and negative terminals, respectively.

15. The system of claim 11, the at least one electrical connector comprising first and second electrical connectors electrically coupled in parallel, for providing an internal bypass for stringing multiple systems together to increase power capacity.

16. The system of claim 11, the at least one electrical connector being a magnetically-attached connector.

17. The system of claim 8, the protection circuitry including a user-resettable circuit breaker triggered by excessive current magnitude.

18. The system of claim 8, the protection circuitry including a mechanical disconnect switch for disconnecting the MSD subsystem from external circuitry.

19. The system of claim 8, the protection circuitry including a magnetically-keyed switch activated through the case of the MSD subsystem, for disconnecting the MSD subsystem from external circuitry.

20. The system of claim 8, the protection circuitry including a wirelessly operated disconnect switch, for disconnecting the MSD subsystem from external circuitry.

21. The system of claim 1, the flexible folding photovoltaic module comprising at least one integrated strap connector for restraining the flexible folding photovoltaic module to the MSD subsystem when the flexible photovoltaic module is stowed.

22. The system of claim 1, the MSD subsystem comprising:
maximum power point tracking circuitry for causing the flexible photovoltaic module to operate at or near its maximum power point;
a battery subsystem for storing and providing electrical power;
charge control circuitry for controlling charging of the battery subsystem;
load management circuitry for generating an internal bus voltage rail and for providing overcurrent protection;
power regulation circuitry to provide power for operating and charging external devices; and
consumer electric-based electrical interfaces for transmitting stored power to external devices.

23. The system of claim 22, the maximum power point tracking circuitry being selected from the group consisting of dynamic maximum power point tracking circuitry and passive maximum power point tracking circuitry.

24. The system of claim 22, further comprising circuitry for providing external power for charging the battery subsystem in lieu of the flexible photovoltaic module.

25. The system of claim 22, further comprising a wireless charging protocol circuit coupled to a matching wireless transmitter for wireless power transmission to an external device.
